(19) United States
(12) Patent Application Publication
(10) Pub. No.: US 2011/0067756 A1
(43) Pub. Date: Mar. 24, 2011

(54) THIN FILM SOLAR CELL

(75) Inventor: Seung-Jae JUNG, Seoul (KR)

(73) Assignee: SAMGUNG ELECTRONICS CO., LTD., Suwon-si (KR)

(21) Appl. No.: 12/862,959

(22) Filed: Aug. 25, 2010

(30) Foreign Application Priority Data
Sep. 21, 2009 (KR) 10-2009-0089265

(51) Int. Cl. H01L 31/0376

(52) U.S. Cl. 136/258; 257/E31.047

(57) ABSTRACT

A thin film solar cell includes; a first electrode, a first active layer disposed on the first electrode, a porous intermediate layer disposed on the first active layer, a second active layer disposed on the intermediate layer and a second electrode disposed on the second active layer.

This application claims priority to Korean Patent Application No. 10-2009-0089265, filed on Sep. 21, 2009, and all the benefits accruing therefrom under 35 U.S.C. §119, the content of which in its entirety is herein incorporated by reference.

### BACKGROUND OF THE INVENTION

1. Field of the Invention

This disclosure relates generally to a thin film solar cell.

2. Description of the Related Art

A solar cell is a photoelectric conversion device that transforms solar energy, or other forms of electromagnetic radiation, into electrical energy, and has attracted much attention as a renewable and pollution-free next generation energy source.

A typical solar cell includes p-type and n-type semiconductors and produces electrical energy by transferring electrons and holes, also referred to as charge-carriers, to the n-type and p-type semiconductors, respectively, and then collects electrons and holes in each electrode when an electron-hole pair (“EHP”), also referred to as an exciton, is produced by solar light energy absorbed in a photoactive layer inside the semiconductors.

Solar cells may be divided into different types, such as a crystalline solar cell and a thin film solar cell. Among the various types of solar cell, the thin film solar cell may be fabricated in a thin film form and has a high light absorption rate in the visible light region compared to the crystalline solar cell. Using a glass substrate or a plastic substrate as a base, the thin film solar cell may be used to fabricate a large-scale solar cell at a relatively low temperature.

Meanwhile, it is important to effectively absorb solar energy emitted from the sun and the increase efficiency of a solar cell at the conversion thereof.

### BRIEF SUMMARY OF THE INVENTION

According to one aspect of this disclosure, an exemplary embodiment of a thin film solar cell includes; a first electrode, a first active layer disposed on the first electrode, a porous intermediate layer disposed on the first active layer, a second active layer disposed on the intermediate layer and a second electrode disposed on the second active layer.

In one exemplary embodiment, the intermediate layer has an average refractive index of about 2 or less.

In one exemplary embodiment, the intermediate layer has an average refractive index of about 1.5 to about 1.9.

In one exemplary embodiment, the intermediate layer may be a porous thin film including a transparent conductive material.

In one exemplary embodiment, the transparent conductive material may include zinc oxide, indium oxide, tin oxide, indium tin oxide (“ITO”), or a combination thereof.

In one exemplary embodiment, the intermediate layer may include a nanostructure including a transparent conductive material.

In one exemplary embodiment, the nanostructure may include nanorods, nanowires, nanotubes, or a combination thereof.

In one exemplary embodiment, the intermediate layer may include pores disposed between the nanostructures.

In one exemplary embodiment, the transparent conductive material may include zinc oxide, indium oxide, tin oxide, indium tin oxide, or a combination thereof.

In one exemplary embodiment, the first active layer may include amorphous silicon, and the second active layer may include one of nano-crystalline silicon and micro-crystalline silicon.

In one exemplary embodiment, the first active layer may have a thinner thickness than a thickness of the second active layer.

According to another aspect of this disclosure, an exemplary embodiment of a thin film solar cell includes; a first electrode, a first active layer disposed on the first electrode, an intermediate layer disposed on the first active layer and including at least two materials, each material of the at least two materials having a different refractive index from each other, a second active layer disposed on the intermediate layer, and a second electrode disposed on the second active layer.

In one exemplary embodiment, the intermediate layer has an average refractive index of about 2 or less.

In one exemplary embodiment, the intermediate layer has an average refractive index of about 1.5 to 1.9.

In one exemplary embodiment, the intermediate layer may include a mixture of a transparent conductive material and a transparent insulating material.

In one exemplary embodiment, the transparent conductive material may include zinc oxide, indium oxide, tin oxide, indium tin oxide, or a combination thereof.

In one exemplary embodiment, the transparent conductive material may be electrically connected to both the first active layer and the second active layer.

In one exemplary embodiment, the transparent insulating material may include silicon oxide, silicon nitride, magnesium fluoride, or a combination thereof.

In one exemplary embodiment, the first active layer may include amorphous silicon, and the second active layer may include one of nano-crystalline silicon and micro-crystalline silicon.

In one exemplary embodiment, the first active layer may have a thinner thickness than a thickness of the second active layer.

### BRIEF DESCRIPTION OF THE DRAWINGS

The above and other aspects, advantages and features of this disclosure will become more apparent by describing in further detail exemplary embodiments thereof with reference to the accompanying drawings, in which:

FIG. 1 is a cross-sectional view illustrating an exemplary embodiment of a thin film solar cell in accordance with one embodiment of the present invention;

FIG. 2 is a schematic diagram describing principles of light absorption and reflection of the exemplary embodiment of a thin film solar cell showing in FIG. 1;

FIG. 3 is a graph showing reflectance according to the refractive index of an intermediate layer of a thin film solar cell; and

FIGS. 4 to 6 are schematic diagrams illustrating exemplary embodiments of an intermediate layer 140 in accordance with one embodiment of the present invention.

### DETAILED DESCRIPTION OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/ or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, the present invention will be described in detail with reference to the accompanying drawings.

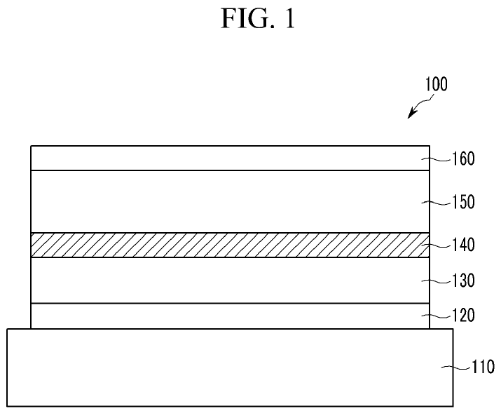

First, referring to FIGS. 1 to 3, an exemplary embodiment of a thin film solar cell 100 according to the present invention will be described.

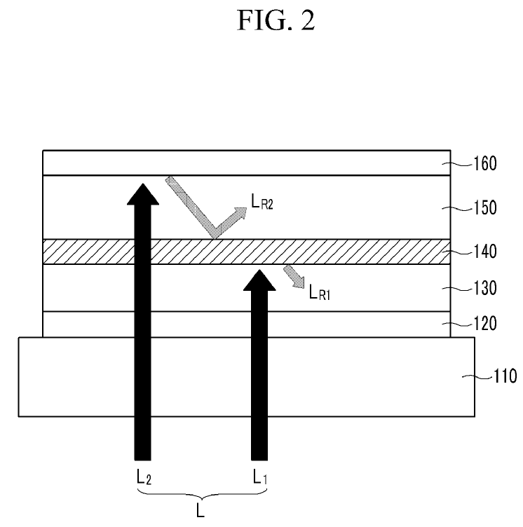

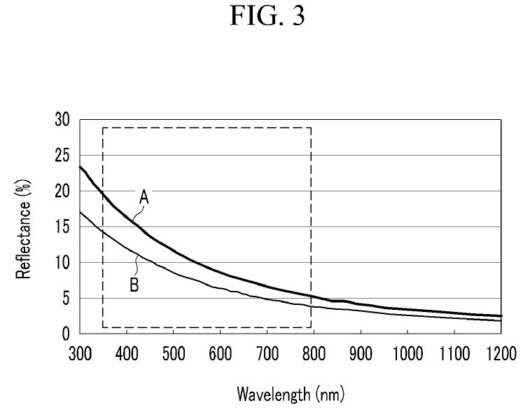

FIG. 1 is a cross-sectional view illustrating an exemplary embodiment of a thin film solar cell in accordance with the present invention, and FIG. 2 is a schematic diagram describing principles of light absorption and reflection of the exemplary embodiment of a thin film solar cell illustrated in FIG. 1. FIG. 3 is a graph showing reflectance according to the refractive index of an intermediate layer of a thin film solar cell.

Referring to FIG. 1, a first electrode 120 is formed on a substrate 110. Exemplary embodiments include configurations wherein the substrate 110 may be made of glass, transparent plastic or other materials having similar characteristics. In the present exemplary embodiment, the first electrode 120 is formed of a transparent conductive oxide (“TCO”). Non-limiting examples of the transparent conductive oxide include SnO₂:F (FTO), ZnO:Al (AZO), ZnO:B, In₂O₃:Sn (indium tin oxide, “ITO”), and other materials having similar characteristics.

In one exemplary embodiment, the first electrode 120 may have a textured surface. Exemplary embodiments of the first electrode 120 with the textured surface may have protrusions and depressions such as in a pyramid shape, or a porous structure such as a honeycomb. The first electrode 120 with the textured surface may increase the amount of effective light absorbed into a solar cell by increasing light scattering and thereby lengthening a light transfer path through the thin film solar cell 100 while reducing reflectance of incident light.

A first active layer 130 is formed on the first electrode 120. The first active layer 130 includes an intrinsic semiconductor layer (not shown) that is capable of absorbing light, and a first impurity doping layer (not shown) and a second impurity doping layer (not shown) disposed in the lower and upper portions of the intrinsic semiconductor layer, respectively. Exemplary embodiments include configurations wherein the first impurity doping layer may be formed of silicon doped with a p-type impurity, and the second impurity doping layer may be formed of silicon doped with an n-type impurity, although the present invention is not limited thereto.

In one exemplary e embodiment, the intrinsic semiconductor layer may be formed of amorphous silicon (a-Si). In such an exemplary embodiment, the amorphous silicon may be intrinsic amorphous silicon or hydrogenated amorphous silicon (a-Si:H), and in the exemplary embodiment including the hydrogenated amorphous silicon, the number of dangling bonds may be reduced and as a result, defects in the intrinsic semiconductor layer may be reduced. The intrinsic semiconductor layer may absorb light and generate charge-carriers such as electrons and holes. Herein, light of a relatively short wavelength ranging from about 300 nm to about 800 nm may be absorbed by the intrinsic semiconductor layer. Exemplary embodiments on the intrinsic semiconductor may have a thickness ranging from about 100 nm to about 500 nm.

The first impurity doping layer and the second impurity doping layer form an internal electric field to separate the charge-carriers generated in the intrinsic semiconductor layer. The first impurity doping layer is a material transparent to the light absorbed by the intrinsic semiconductor layer, that is, the first impurity doping layer may be formed of a material having high electrical conductivity and low light absorbance for the wavelength of photon absorbed by the intrinsic semiconductor layer. In one exemplary embodiment, the first impurity doping layer and the second impurity doping layer may have a thickness ranging from about 10 nm to about 50 nm, individually.

According to one exemplary embodiment, an intermediate layer 140 may be formed on the first active layer 130.

The intermediate layer 140 is disposed between the first active layer 130 and a second active layer 150, and functions as a buffer layer for reducing defects that may be caused by different doping layers sharing an interface with one another.

Also, the intermediate layer 140 functions as a selective light transmission layer that reflects light of a first predetermined wavelength which can be absorbed by the first active layer 130 and transmits light of a second predetermined wavelength which can be absorbed by the second active layer 150.

Exemplary embodiments include configurations wherein the intermediate layer 140 may be formed of a transparent material, which is a selective light transmission material that transmits light of a first predetermined wavelength region while reflecting light of a second predetermined wavelength region. As described briefly above, in one exemplary embodiment, the selective light transmission material may reflect light of the first predetermined wavelength which can be absorbed by the first active layer 130 and transmit light of the second predetermined wavelength which can be absorbed by the second active layer 150.

Herein, when the intermediate layer 140 has a low refractive index and the intermediate layer 140 may effectively reflect the light having the wavelength range absorbed by the first active layer 130. In such an exemplary embodiment, the average refractive index of the intermediate layer 140 may be lower than about 2. In one exemplary embodiment the average refractive index of the intermediate layer 140 may range from about 1.5 to about 1.9. In another exemplary embodiment the average refractive index of the intermediate layer 140 may range from about 1.6 to about 1.8.

Hereafter, further description of the exemplary embodiment of a solar cell 100 will be given with reference to FIG. 2.

Referring to FIG. 2, light (L) entering from the substrate 110 roughly includes light (L1) having a relatively shorter wavelength range and light (L2) having a relatively longer wavelength range. Among the lights L1 and L2, the light (L1) of the short wavelength range may be usually absorbed in the first active layer 130, e.g., in one exemplary embodiment the first active layer 130 is selected to absorb light at a shorter wavelength range, and some light of the short wavelength range that is not absorbed by the first active layer 130 may be reflected (LR1) from the intermediate layer 140 and re-absorbed in the first active layer 130. Herein, when the intermediate layer 140 has a low refractive index, the amount of light (LR1) reflected from the surface may be increased due to internal reflection, and accordingly, the amount of light that is re-absorbed in the first active layer 130 may be increased.

Meanwhile, the light (L2) of a long wavelength range is not absorbed by the first active layer 130 but is transmitted through the intermediate layer 140 and mainly absorbed in the second active layer 150, e.g., in one exemplary embodiment the second active layer 150 is selected to absorb light at a longer wavelength range. The light of the long wavelength that is not absorbed by the second active layer 150 may be reflected (LR2) from a second electrode 160 and the intermediate layer 140, and be reabsorbed by the second active layer 150.

As described above, the intermediate layer 140 may have increased reflectance at the surface thereof by having a low refractive index.

This will be described hereafter with reference to FIG. 3.

Referring to FIG. 3, reflectance differs according to an average refractive index of the intermediate layer 140. When an intermediate layer 140 having an average refractive index of about 1.7 (illustrated by line “A”) is compared with an intermediate layer 140 having an average refractive index of about 2.0 (illustrated by line “B”), the intermediate layer 140 having an average refractive index of about 1.7 has higher reflectance. This effect is more prominent in a region corresponding to a short wavelength ranging from about 300 nm to about 800 nm (surrounded by the dotted line in FIG. 3). It may be seen from the result that the amount of light reflected and reabsorbed by the first active layer 130 may be increased by decreasing the average refractive index of the intermediate layer.

As seen above, the amount of light (LR1) reflected from the intermediate layer 140 and returning to the first active layer 130 may be increased by increasing the reflectance thereof at the wavelength corresponding to the absorptive wavelength of the first active layer 130 and thus the efficiency of the first active layer 130 may be increased, e.g., more light passing through that layer may be used to generate electricity. Also, since the thickness of the first active layer 130 may be reduced corresponding to a gain of light absorption acquired from the reflection of the intermediate layer 140 while still maintaining the same overall electrical generation, it is possible to decrease a light degradation of the first active layer 130 occurring in proportion to a light path according to the thickness thereof. Therefore, the first active layer 130 may be designed to be thinner than the second active layer 150, and accordingly an efficiency deterioration caused by the light degradation may be reduced.

In one exemplary embodiment the intermediate layer 140 may have a thickness ranging from about 10 nm to about 200 nm. In another exemplary embodiment, the thickness of the intermediate layer 140 may be from about 20 nm to about 100 nm.

The second active layer 150 is formed on the intermediate layer 140. Similar to the first active layer 130, exemplary embodiments of the second active layer 150 also includes a first impurity doping layer (not shown), an intrinsic semiconductor layer (not shown) and a second impurity doping layer (not shown).

Exemplary embodiments of the intrinsic semiconductor layer of the second active layer 150 may be formed of amorphous silicon, amorphous silicon germanium (a-SiGe), nano-crystalline silicon, micro-crystalline silicon or other materials having similar characteristics.

In one exemplary embodiment, the amorphous silicon germanium may be hydrogenated amorphous silicon germanium (a-SiGe:H). The amorphous silicon germanium, nano-crystalline silicon, and micro-crystalline silicon have a smaller bandgap than that of amorphous silicon, and therefore the second active layer 150 including such materials may absorb light of a relatively longer wavelength ranging from about 300 nm to about 1200 nm.

When light enters the substrate 110, some of that light having a predetermined wavelength range may be absorbed by the first active layer 130, and some light having another wavelength range may be transmitted through the intermediate layer 140 and be absorbed by the second active layer 150. For example, in one exemplary embodiment among the incident light, light having a short wavelength range may be absorbed by the first active layer 130 to thereby generate an optical current, and light of a long wavelength range may be transmitted through the intermediate layer 140 and be absorbed by the second active layer 150 to thereby generate an optical current.

The second electrode 160 is formed on the second active layer 150. Exemplary embodiments of the second electrode 160 may be formed of aluminum (Al), silver (Ag), a combination thereof or other materials having similar characteristics.

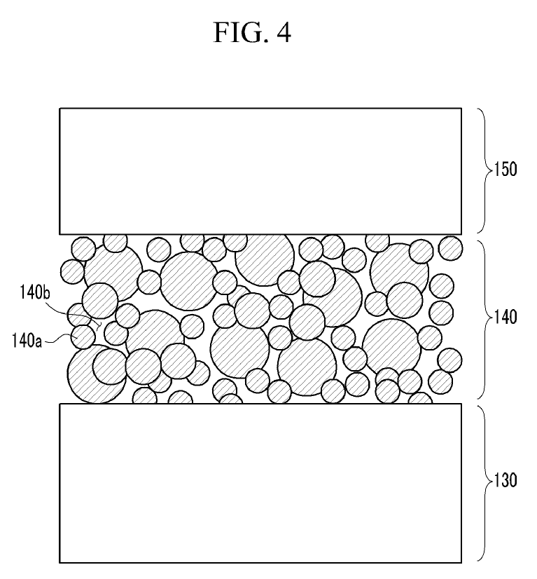

Hereafter, referring to FIGS. 4 to FIG. 6, an exemplary embodiment of a method for forming an intermediate layer 140 having a low refractive index will be described.

FIGS. 4 to 6 are schematic diagrams illustrating an exemplary embodiment of an intermediate layer 140 in accordance with the present invention.

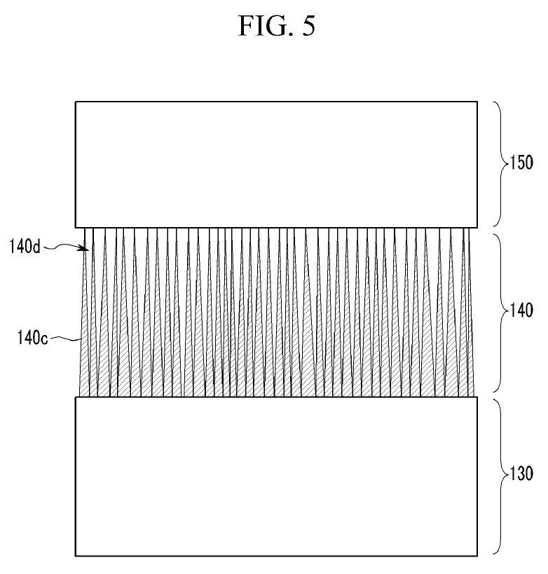

Referring to FIGS. 4 and 5, the intermediate layer 140 may have a porous structure having a plurality of pores, e.g., pores 140b in FIG. 4 and pores 140d in FIG. 5.

Referring to FIG. 4, the intermediate layer 140 may be a porous thin film including a transparent conductive material. The porous thin film may be formed of a small particle-type transparent conductive material 140a having a plurality of pores 140b disposed between the individual particles of the particle-type transparent conductive material 140a.

Exemplary embodiments of the transparent conductive material may include zinc oxide, indium oxide, tin oxide, ITO, or a combination thereof, and the porous structure may be formed through a chemical vapor deposition (“CVD”), sputtering, ion plating, pulsed laser deposition (“PLD”), a solution process or various other similar methods. Herein, the size and distribution amount of the pores 140b may be controlled based on the formation conditions of the transparent conductive material.

Referring to FIG. 5, the intermediate layer 140 may have a nanostructure 140c including the transparent conductive material. Exemplary embodiments of the transparent conductive material may include zinc oxide, indium oxide, tin oxide, ITO, a combination thereof, or other materials having similar characteristics and the nanostructure 140c may be nanorods, nanowires, nanotubes, a combination thereof or other structures having similar characteristics. A plurality of the pores 140d may be formed between the nanostructures 140c.

Exemplary embodiments of the nanostructure 140c may be grown out of a metal catalyst, taken as a seed, grown through a method of dipping a substrate in an electrolyte solution or other similar methods.

As described above, because the intermediate layer 140 has a porous structure including a plurality of pores 140b and 140d, the average refractive index may be decreased. Herein, the average refractive index may be calculated as an average value of the refractive index of the transparent conductive material and the refractive index of the pores taken together. Exemplary embodiments of the refractive index of the transparent conductive material may be equal to or greater than about 2. Exemplary embodiments also include configurations wherein the refractive index of the transparent conductive material may range from about 2.0 to about 2.3. In one exemplary embodiment, the refractive index of the pores is substantially the same as the refractive index of air, which is 1. Therefore, the porous intermediate layer 140 may have an average of the refractive index of the transparent conductive material and the refractive index of the pores, and that average refractive index may be smaller than 2.

In an exemplary embodiment where the intermediate layer 140 has a low refractive index, the reflectance at the surface of the intermediate layer 140 may be increased and the amount of light reflected to the first active layer 130 may be increased.

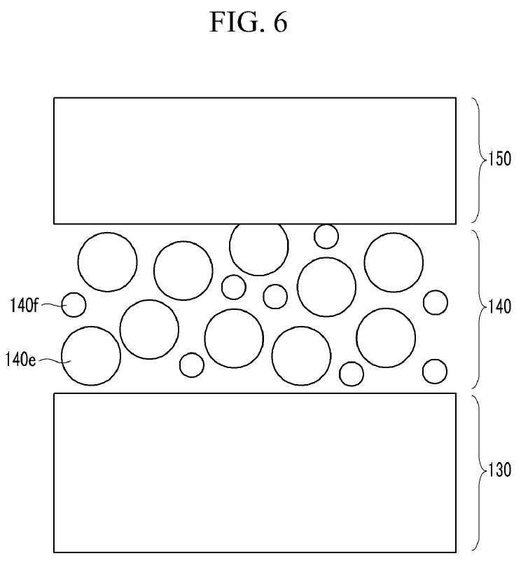

Referring to FIG. 6, another exemplary embodiment of the intermediate layer 140 may include a mixture of at least two different materials having different refractive indexes, respectively.

One of the at least two materials having different refractive indexes is a transparent conductive material 140e, and as described above, exemplary embodiments of the transparent conductive material 140e include zinc oxide, indium oxide, tin oxide, ITO, a combination thereof and other materials having similar characteristics. In one exemplary embodiment, the transparent conductive material has a refractive index equal to or higher than about 2, and the refractive index may range from about 2.0 to about 2.3.

Another of the at least two materials having different refractive indexes may be a transparent material having a lower refractive index than that of the transparent conductive material 140e, and it may be a transparent insulating material 140f. Exemplary embodiments of the transparent insulating material 140f may include silicon oxide (SiO₂), silicon nitride (SiNₓ), magnesium fluoride (MgF₂), a combination thereof or other materials with similar characteristics. Herein, the refractive indexes of the silicon oxide, nitrogen oxide, and magnesium fluoride are about 1.46, about 1.75, and about 1.38, respectively, and the average refractive index may be controlled to be lower than about 2 by mixing the transparent insulating material 140f with the transparent conductive material 140e.

Exemplary embodiments of the at least two materials 140e and 140f may be formed through a process such as chemical vapor deposition (“CVD”), sputtering, a solution process, a combination thereof or other similar processes. In the exemplary embodiment wherein they are formed through the solution process, each material is prepared in the form of a precursor that may exist in a liquid phase, and they are mixed with each other, applied, and undergo heat treatment.

Herein, the transparent conductive material 140e may be formed in a structure where the upper and lower portions are electrically connected. For example, the transparent conductive material 140e may form a continuous phase in the upper and lower direction between the first active layer 130 and the second active layer 150. Accordingly, the first active layer 130 and the second active layer 150 may be electrically connected through the transparent conductive material 140e.

By mixing the materials, it is possible to control the refractive index to lower than about 2 and thereby increase the reflectance at the surface of the intermediate layer 140 while securing transparency and conductivity, and to increase the amount of light reflected to the first active layer 130.

Herein, the mixing ratio of the two materials may be controlled based on the following Equation 1 and a desired refractive index.

Average Refractive Index (n)=n₁×V₁+n₂×V₂ <Equation 1>

wherein, n₁ denotes the refractive index of the transparent conductive material, V₁ denotes the volume ratio of the transparent conductive material, n₂ is the refractive index of the transparent insulating material, and V₂ is a volume ratio of the transparent insulating material.

For example, when zinc oxide (ZnO) having a refractive index of about 2.0 is mixed with silicon oxide (SiO₂) having a refractive index of about 1.46 at a mixing ratio of about 70:30, respectively, because 2.0×0.7+1.46×0.3=1.838, the average refractive index becomes 1.838, which is lower than a refractive index of 2 of the zinc oxide (ZnO) itself.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A thin film solar cell comprising:
a first electrode;
a first active layer disposed on the first electrode;
a porous intermediate layer disposed on the first active layer;
a second active layer disposed on the intermediate layer; and
a second electrode disposed on the second active layer.

2. The thin film solar cell of claim 1, wherein the intermediate layer has an average refractive index of about 2 or less.

3. The thin film solar cell of claim 2, wherein the intermediate layer has an average refractive index of about 1.5 to about 1.9.

4. The thin film solar cell of claim 2, wherein the intermediate layer is a porous thin film including a transparent conductive material.

5. The thin film solar cell of claim 4, wherein the transparent conductive material is a material selected from the group consisting of zinc oxide, indium oxide, tin oxide, indium tin oxide and a combination thereof.

6. The thin film solar cell of claim 2, wherein the intermediate layer comprises a nanostructure comprising a transparent conductive material.

7. The thin film solar cell of claim 6, wherein the nanostructure is selected from the group consisting of nanorods, nanowires, nanotubes and a combination thereof.

8. The thin film solar cell of claim 7, wherein the intermediate layer comprises pores disposed between the nanostructures.

9. The thin film solar cell of claim 6, wherein the transparent conductive material is selected from the group consisting of zinc oxide, indium oxide, tin oxide, indium tin oxide and a combination thereof.

10. The thin film solar cell of claim 1, wherein the first active layer comprises amorphous silicon, and
the second active layer comprises one of nano-crystalline silicon and micro-crystalline silicon.

11. The thin film solar cell of claim 10, wherein the first active layer has a thinner thickness than a thickness of the second active layer.

12. A thin film solar cell comprising:
a first electrode;
a first active layer disposed on the first electrode;
an intermediate layer disposed on the first active layer and including at least two materials, each material of the at least two materials having a different refractive index from each other;
a second active layer disposed on the intermediate layer; and
a second electrode disposed on the second active layer.

13. The thin film solar cell of claim 12, wherein the intermediate layer has an average refractive index of about 2 or less.

14. The thin film solar cell of claim 13, wherein the intermediate layer has an average refractive index of about 1.5 to about 1.9.

15. The thin film solar cell of claim 13, wherein the intermediate layer comprises a mixture of a transparent conductive material and a transparent insulating material.

16. The thin film solar cell of claim 15, wherein the transparent conductive material is selected from the group consisting of zinc oxide, indium oxide, tin oxide, indium tin oxide and a combination thereof.

17. The thin film solar cell of claim 15, wherein the transparent conductive material is electrically connected to both the first active layer and the second active layer.

18. The thin film solar cell of claim 15, wherein the transparent insulating material is selected from the group consisting of silicon oxide, silicon nitride, magnesium fluoride and a combination thereof.

19. The thin film solar cell of claim 12, wherein the first active layer comprises amorphous silicon, and
the second active layer comprises one of nano-crystalline silicon and micro-crystalline silicon.

20. The thin film solar cell of claim 19, wherein the first active layer has a thinner thickness than a thickness of the second active layer.
